(19) United States
(12) Patent Application Publication
(10) Pub. No.: US 2024/0018650 A1
(43) Pub. Date: Jan. 18, 2024

(54) METHOD FOR PRODUCING X-RAY PHASE GRATINGS AND X-RAY GRATINGS PRODUCED BY THE METHOD

(71) Applicant: Houxun Miao, Zionsville, IN (US)

(72) Inventor: Houxun Miao, Zionsville, IN (US)

(21) Appl. No.: 17/812,872

(22) Filed: Jul. 15, 2022

(51) Int. Cl. C23C 16/455; G21K 1/06; C23C 16/40; C23C 16/34

(52) U.S. Cl. CPC C23C 16/45529; G21K 1/067; C23C 16/402; C23C 16/403; C23C 16/34

(57) ABSTRACT

Disclosed herein is a method to produce hard x-ray phase gratings for x-ray multi-contrast imaging. The method is based on the conformal atomic layer deposition (ALD) of material with high x-ray refractive index decrement δ. The method is particularly suitable for submicron period x-ray phase grating fabrication. The fabrication process to produce x-ray phase gratings in this disclosure is compatible with standard semiconductor fabrication instrument and suitable for mass production.

### GOVERNMENT INTEREST STATEMENT

This invention was made with government support R43EB028224 awarded by the National Institute of Biomedical Imaging and Bioengineering (NIBIB), National Institutes of Health (NIH). The government has certain rights to the invention.

### CROSS REFERENCE TO RELATED APPLICATIONS

N/A

### FIELD

The present invention relates to a method for producing x-ray phase gratings, suitably used for x-ray interferometric systems to realize x-ray phase contrast imaging. The invented method is particularly suitable for fabrication of x-ray phase gratings with submicron and deep submicron half pitch.

### BACKGROUND

X-ray imaging has been used for medical diagnosis for more than a hundred years. X-ray phase contrast imaging with gratings, using medical x-ray tubes, provides a method to detect phase and small angle scattering contrasts in addition to the absorption contrast, suitable for implementation in hospitals for clinical utilization. Among grating-based x-ray phase contrast imaging systems, x-ray polychromatic far field interferometer uses 3 phase gratings to significantly improve the phase and scattering contrasts compared to Talbot-Lau interferometer [Miao, Houxun, et al. “A universal moiré effect and application in X-ray phase-contrast imaging.” Nature physics 12.9 (2016): 830-834.]. Universal moiré effect based two-phase-grating x-ray interferometers produce phase and dark-field contrasts without degrading the absorption contrast at the same patient dose level (since no gratings are needed between the image object and the x-ray detector) with reduced interferometer complexity. X-ray phase gratings are key components for highly sensitive x-ray polychromatic far field interferometers and compact two-phase-grating x-ray interferometers. Large period (e. g. a few microns) x-ray phase gratings can easily be made by deeply etching Si gratings to the desired depth or by x-ray lithography patterning of a polymer grating mold and then filling the grating trenches via electroplating of Ni or Au. Small period x-ray phase gratings are difficulty to produce, due to the required high aspect ratio of pure Si gratings and the difficulty to create high aspect ratio and small period polymer molds, and to fill the mold trenches with strong x-ray phase shifting material.

In the prior art [Miao, Houxun, et al. “Fabrication of 200 nm period hard X-ray phase gratings.” Nano letters 14.6 (2014): 3453-3458.], a process has been used to fabricate a few hundred nm period Si/Au x-ray phase gratings. The process uses nanoimprint lithography and cryogenic deep Si etching to fabricate high aspect ratio Si gratings. Atomic layer deposition (ALD) is used to form a seed layer of Pt on the Si grating. A thin layer of Al₂O₃ is ALDed between the Si and the Pt film to facilitate platinum nucleation and improve adhesion. Au is then conformally electrodeposited until the trenches are completely filled with Au.

### SUMMARY

An object of the present invention is to provide a method for the fabrication of small period x-ray phase gratings for x-ray phase contrast imaging. Another object of the present invention is to provide small period x-ray phase gratings fabricated by the method.

The invention is based on the insight that among the materials that can be conformally deposited into high aspect ratio trenches via ALD, there are compounds and metals that have x-ray refractive index decrement δ (1 subtract the real part of the x-ray refractive index) at least twice that of Si. For small period x-ray phase grating fabrication with a desired phase shift, the required aspect ratio for a Si grating is usually too high for current fabrication techniques to reliably produce. For example, a 600 nm period it-phase shift Si grating at 30 keV will require a grating teeth height of ≈38.5 μm, corresponding to an aspect ratio of ≈128:1. By depositing a material or a combination of materials with average 6 greater than twice that of Si to form a grating consisting of the deposited material(s) and Si, the required aspect ratio is effectively reduced.

In one embodiment, the process consists of fabricating a Si grating with desired depth, controlling the duty cycle of the grating by wet or dry oxidation of the Si grating in a furnace or by ALD deposition of SiO₂ or Al₂O₃, or any other materials that have an x-ray refractive index decrement δ close to that of Si, performing ALD to fill the grating trenches with material with high x-ray refractive index decrement δ, or materials with high δ in average (at least twice that of Si). The Si grating may have a high aspect ratio, for example, a grating having an aspect ratio of at least 5, for example, at least 10 or at least 20.

In one embodiment, the process consists of fabricating a Si grating with Si teeth width less than half the grating period and performing ALD to deposit a layer of high x-ray refractive index decrement δ material or a layer of combined materials with high δ in avarage such that the sum of the Si teeth width and the deposited material thickness is approximately half the grating period. In one embodiment, the air gap is filled via ALD with material that has δ close to that of Si, for example, SiO₂ or Al₂O₃ deposited at low temperature, for example, 150° C. In one embodiment, the air gap is left unfilled because the refractive index difference between Si and air is much less than that between deposited material(s) and Si. The fabricated device overall performs as an x-ray grating with a period half that of the initial Si grating mold.

### BRIEF DESCRIPTION OF THE DRAWINGS

The embodiments of the present invention will become better understood with reference to the following drawings. It is noted that, for purpose of illustrative clarity, certain elements in various drawings may not be drawn to scale. These drawings depict exemplary embodiments of the disclosure, but should not be considered to limit its scope. Preferred examples and embodiments are described hereinafter with reference to the accompanying drawings, wherein:

FIG. 1 is a schematic illustration of the cross-section view of a prior art Si/Au x-ray phase grating.

FIG. 2 is a schematic illustration of the cross-section view of an x-ray phase grating, according to one embodiment of the present invention.

FIG. 3 is a schematic illustration of the cross-section view of an x-ray phase grating, where the low x-ray refractive index decrement δ grating teeth consist of multiple materials, according to one embodiment of the present invention.

FIG. 4 is a schematic illustration of the cross-section view of an x-ray phase grating, where the high x-ray refractive index decrement δ grating teeth consist of multiple materials, according to one embodiment of the present invention.

FIG. 5 is a schematic illustration of the cross-section view of an x-ray phase grating, where the effective grating period is one half that of the Si grating mold and the air gap is left unfilled, according to one embodiment of the present invention.

FIG. 6 is a schematic illustration of the cross-section view of an x-ray phase grating, where the grating period is one half that of the Si grating mold and a low x-ray refractive index decrement δ material is deposited to fill the gap after the high δ material deposition, according to one embodiment of the present invention.

FIG. 7 is a schematic illustration of the top view of a Si grating mold to be filled with high x-ray refractive index decrement δ material or materials, where cross-bridges are used to improve the mechanical property, according to one embodiment of the present invention.

FIG. 8 is the cross-section SEM image of a fabricated x-ray phase grating, where the high x-ray refractive index decrement δ material WN is deposited via ALD to fill the trenches of the Si grating mold, according to one embodiment of the present invention.

FIG. 9 is the cross-section SEM image of a fabricated x-ray phase grating, where the low x-ray refractive index decrement δ materials consists of Si and SiO₂, the high x-ray refractive index decrement δ materials consists of multiple layers of 5 nm Al₂O₃/25 nm W, according to one embodiment of the present invention.

FIG. 10 is the cross-section SEM image of a fabricated x-ray phase grating, where the phase grating period is half that of the Si grating mold, the high x-ray refractive index decrement δ material is WN, and the air gap is left unfilled, according to one embodiment of the present invention.

### DETAILED DESCRIPTION

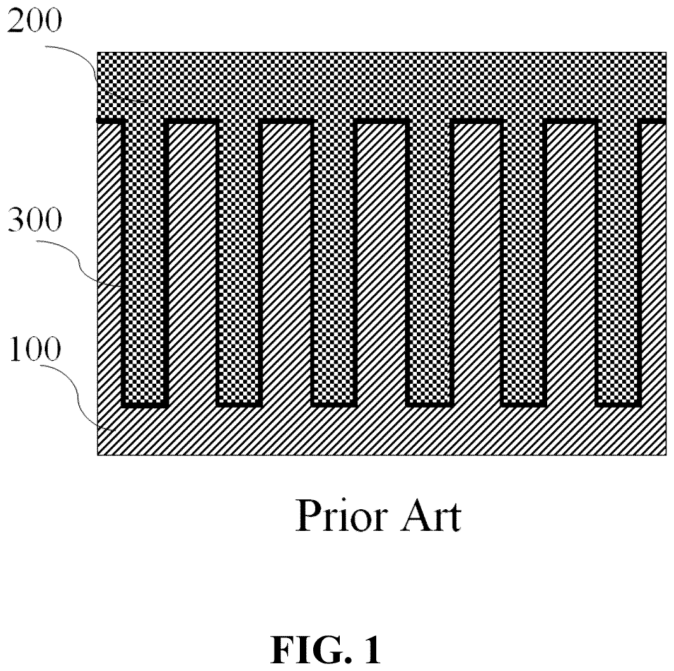

In the prior art research [Mico, Houxun, et al. “Fabrication of 200 nm period hard X-ray phase gratings.” Nano letters 14.6 (2014): 3453-3458.], submicron period hard x-ray phase gratings (Refer to FIG. 1) were fabricated by creating a high aspect ratio Si grating mold 100 via cryogenic deep Si etching, coating the entire exposed grating surface (including the top, side wall and bottom surface) with a Pt seed layer 300 using a thin layer of Al₂O₃ as nucleation layer via ALD, and then fill the Si grating trenches with Au 200 via conformal electrodeposition. The combined dry and wet processes, particularly the poor uniformity of the electrodeposition process over a large area grating, make the fabrication process complicated and reduce the yield of production. The electrodeposition of Au was performed at constant current. The Au was easily over deposited at the top of the grating surface (as sketched in FIG. 1) because there was a sudden increase of the current density once the grating trenches are filled with Au. The excessive Au on the grating top introduces unnecessary absorption of x-rays. A polishing process to remove the excessive Au further complicates the fabrication process.

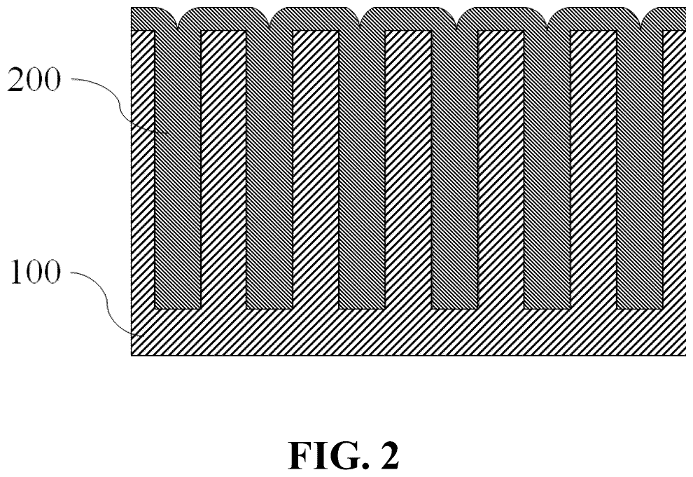

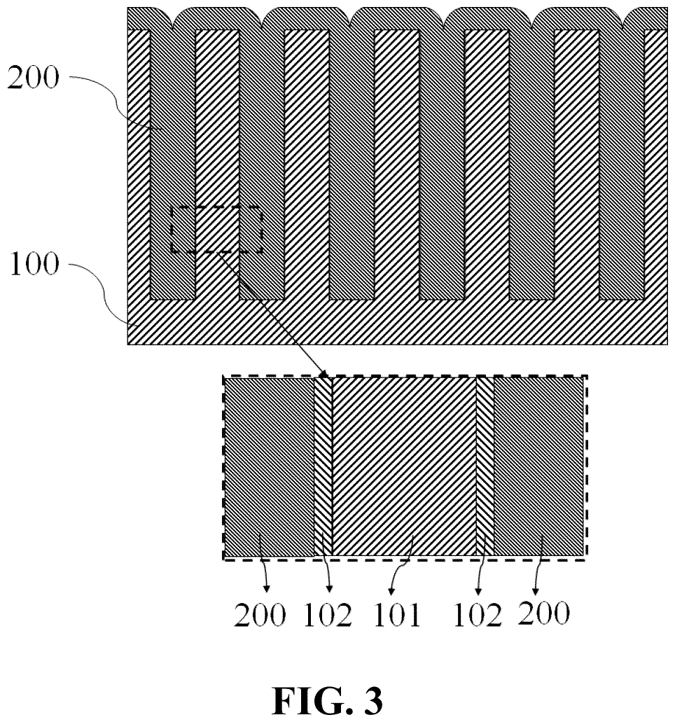

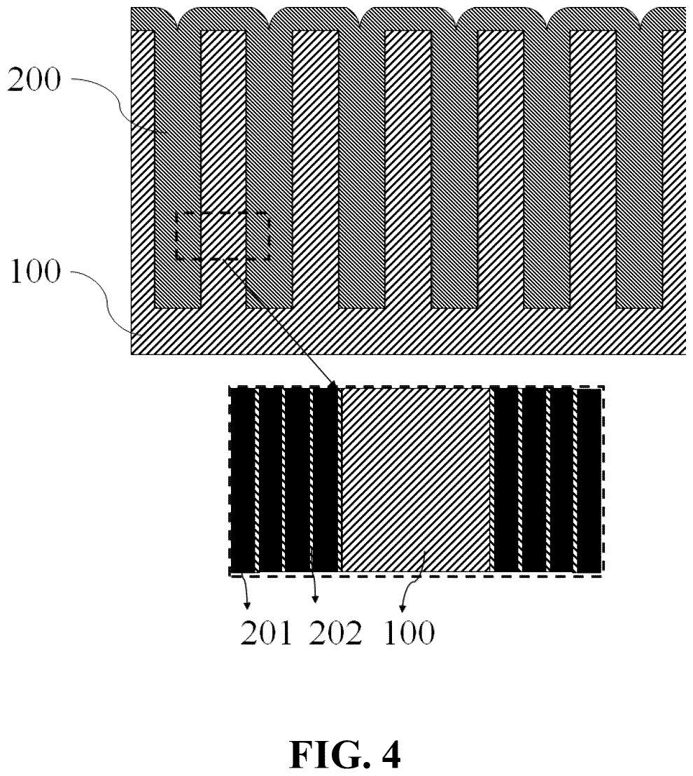

The method in this disclosure takes advantages of the broad range of materials, particularly high x-ray refractive index decrement δ materials, that can be deposited via ALD with high conformality to fill or partly fill high aspect ratio grating trenches. The method in this disclosure to produce x-ray phase grating with the same period as the grating mold (refer to FIGS. 2-4) involves:
1. Create a high aspect ratio grating mold 100 with low x-ray refractive index decrement δ material (refer to FIG. 2) or materials (refer to FIG. 3).
2. Conformally coat material (refer to FIGS. 2 and 3) or materials (refer to FIG. 4) 200 with high δ or high δ in average via ALD to fill the trenches of the grating mold.

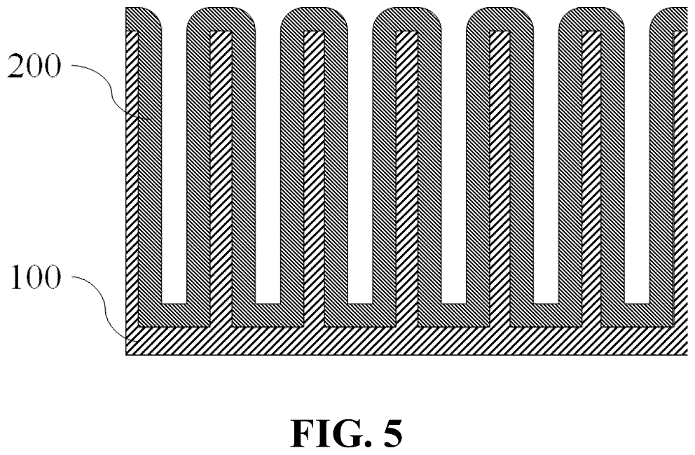

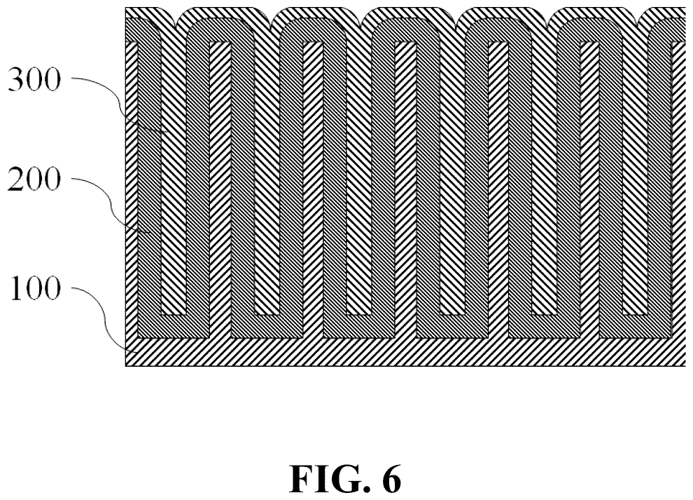

The method to produce x-ray phase grating with period half that of the grating mold (refer to FIGS. 5 and 6) involves:
1. Create a high aspect ratio grating mold 100 with low x-ray refractive index decrement δ material or materials, where the grating teeth width is less than ½ the grating period, preferably ¼ the grating period.
2. Conformally coat material with high δ or materials with high δ in average 200 via ALD such that the sum of the grating mold teeth width and the deposited material or materials thickness is approximately half the grating period.
3. Leave the air gap unfilled (refer to FIG. 5), or conformally coat material or materials with δ close to that of the material or materials of the teeth of the mold grating via ALD to fill the airgap (refer to FIG. 6).

Various embodiments of the disclosure are discussed in details below. While specific implementations are discussed, it should be understood that this is done for illustration purposes only. A person skilled in the relevant art will recognize that other components and configurations may be used without parting from the spirit and scope of the disclosure. Thus, the following description, drawings and examples are illustrative and are not to be construed as limiting.

In one embodiment of the present invention (refer to FIG. 2), a Si grating of submicron (for example, 600 nm) period with a duty cycle of ≈50% is used as the grating mold 100. A compound with high x-ray refractive index decrement (δₕ) 200 is conformally deposited via ALD to fill the trenches of the grating mold. The depth (d) of the Si grating is determined by the x-ray wavelength (λ), the x-ray refractive index decrement (δₕ) of the ALD deposited high δ material 200 and the required x-ray phase shift (θ) as d=λθ/[2π(δₕ−δ_{Si})], where δ_{Si} is the x-ray refractive index decrement of Si. Typical high x-ray refractive index decrement compounds for 200 that can conveniently be conformally deposited via ALD include (but not limited to) WN, TaN, and HfN.

In one embodiment of the present invention (refer to FIG. 3), the grating mold 100 consists of a submicron period Si grating (for example, 600 nm period) 101 and a thin layer of material or materials 102 with x-ray refractive index decrement δ close to that of Si conformally deposited to both sides of each of the Si grating teeth to adjust the grating duty cycle. Typical materials with x-ray refractive index decrement δ close to that of Si include (but not limited to) SiO₂ and Al₂O₃. When SiO₂ is used to adjust the duty cycle, wet or dry oxidation, or ALD can be used to deposit the material. When other materials are used, ALD is used to conformally deposit the materials. When Al₂O₃ is deposited via ALD, the process temperature is preferred to be low (for example, at 150° C.) to keep the x-ray refractive index decrement δ close to that of Si. A compound 200 with high x-ray refractive index decrement δ is conformally deposited via atomic layer deposition to fill the trenches of the grating mold.

In one embodiment of the present invention (refer to FIG. 4), a Si grating of submicron (for example, 600 nm) period with a duty cycle of ≈50% is used as the grating mold 100. A stack of multiple high atomic number metal 201/dielectric 202 bilayers are deposited to fill the grating trenches. The high atomic number metals that can conveniently be ALDed include (but not limited to) W, Ta, Pt, Au, and Ir. The dielectric material is preferred (but not limited to) to be Al₂O₃, which also acts as a nucleation layer. The underline reason to use a stack of high atomic number metal/dielectric bilayers is to avoid the delamination of the ALD deposited metal layer, particularly when a thick layer of material (for example, 150 nm) is required to fill the grating trenches. The depth (d) of the Si grating is determined by the x-ray wavelength (λ), the average x-ray refractive index decrement (δ_{avg}) of the ALD deposited multiple layer material 200 and the required x-ray phase shift (θ) as d=λθ/[2π(δ_{avg}−δ_{Si})], where δ_{Si} is the x-ray refractive index decrement of Si. In the stack of the metal/dielectric film, the volume percentage of the metal is preferred to be at least 80% to achieve high average x-ray refractive index decrement (δ_{avg}). An alternative method to solve the metal delamination problem is to deposit the metal via ALD at low temperature, for example, ALD W with a WF₆—Si₂H₆ process at 80° C.

In one embodiment of the present invention (refer to FIG. 5), a Si grating of 600 nm period with a Si teeth width of 150 nm is used as the grating mold 100. A compound film of 150 nm thickness with high x-ray refractive index decrement (δₕ) 200 is conformally deposited via ALD. The 150 nm air gaps in the grating trenches are left unfilled. The resulted x-ray phase grating has an effective period half that of the Si grating mold and a slightly different phase shift of the Si grating teeth and the air gap grating teeth. The desired depth (d) of the Si grating is determined by the x-ray wavelength (λ), the x-ray refractive index decrement (δₕ) of the ALD deposited high x-ray refractive index decrement material 200 and the required x-ray phase shift (θ) between the Si teeth and the δₕ material teeth as d=λθ/[2π(δₕ−δ_{Si})], where δ_{Si} is the x-ray refractive index decrement of Si. Typical high x-ray refractive index decrement δₕ compounds for 200 that can conveniently be conformally ALD deposited include (but not limited to) WN, TaN, and HfN.

In one embodiment of the present invention (refer to FIG. 6), a Si grating of 600 nm period with a Si teeth width of 150 nm is used as the grating mold 100. A compound film 200 of 150 nm thickness with high x-ray refractive index decrement (δₕ) is conformally deposited via ALD. Then a compound material 300 with x-ray refractive index decrement δ close to that of Si is conformally deposited via ALD to fill the trenches. The resulted x-ray phase grating has a period half that of the Si grating mold. The depth (d) of the Si grating is determined by the x-ray wavelength (λ), the x-ray refractive index decrement (δₕ) of the ALD deposited high δ material 200 and the required x-ray phase shift (θ) as d=λθ/[2π(δₕ−δ_{Si})], where δ_{Si} is the x-ray refractive index decrement of Si. Typical high x-ray refractive index decrement compounds for 200 that can conveniently be conformally ALD deposited include (but not limited to) WN, TaN, and HfN. Typical compounds for 300 that can conveniently be conformally ALD deposited include (but not limited to) SiO₂, Al₂O₃. When Al₂O₃ is used, the ALD process temperature is preferred to be low (for example, at 150° C.) to keep the x-ray refractive index decrement δ close to that of Si.

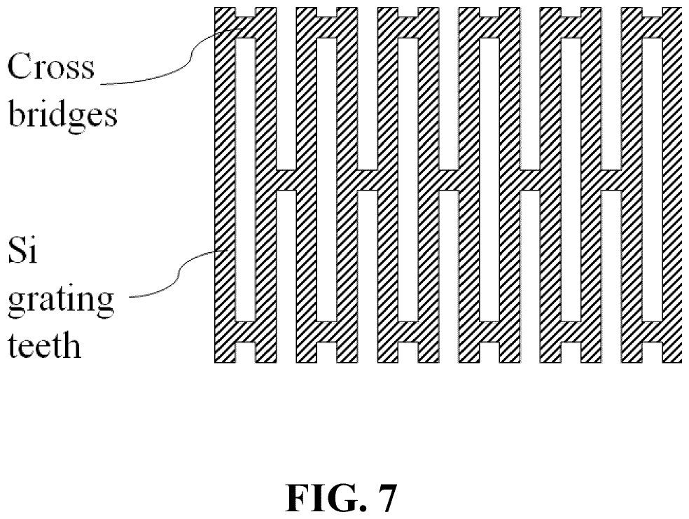

In one embodiment of the present invention (refer to FIG. 7), cross bridges are used to improve the mechanical property of the Si grating mold. The cross bridges can take for example, 5% to 20% of the grating area. The cross bridges can be used in all the embodiments discussed above to support the grating structures from collapse caused by the stress imposed by the ALD deposited materials, particularly, when the aspect ratio of the Si grating mold is high and the ALD deposited film (films) is (are) thick.

The fabrication process of x-ray phase gratings in this disclosure is compatible with standard semiconductor fabrication process and suitable for mass production. The fabrication process involves creating a Si grating mold, conformally filling or partly filling the trenches of the Si grating mold with high x-ray refractive index decrement (δ) material or materials with high δ in average. When the Si grating mold trenches are partly filled, the air gap can remain unfilled or be filled with a material with x-ray refractive index decrement close to that of Si. The Si grating mold can be conveniently fabricated via deep reactive ion etching (DRIE) using a Bosch process, cryogenic deep Si etching, KOH etching, metal assisted chemical etching (MACE) of Si and photoelectrochemical etching of Si. When a layer of SiO₂ is used to adjust the duty cycle of the Si grating mold, it can be grown conformally via wet or dry oxidation, or deposited via ALD. All the other materials can be conformally deposited via ALD.

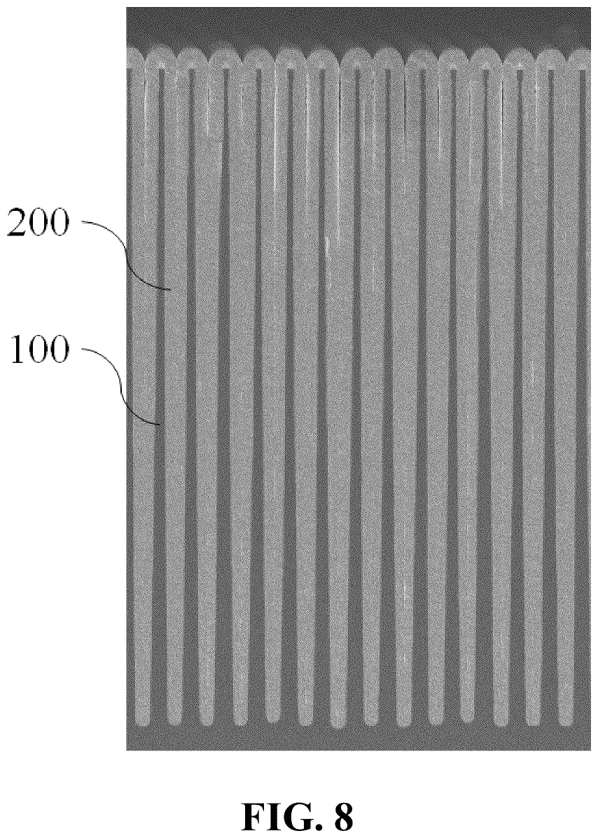

In one embodiment of the fabrication process, a Si grating mold 100 (refer to FIG. 8) of 600 nm period, 12 μm depth was fabricated via DRIE. A layer of 200 nm WN 200 was conformally deposited via ALD to fill the trenches of the Si grating mold, resulting in a Si/WN x-ray phase grating. The WN film was ALD deposited with Bis(tert-butylimido)-bis(dimethylamido)tungsten(VI) (((CH₃)₃CN)₂W(N(CH₃)₂)₂) and ammonia (NH₃) precursors at 300° C. The average width (along the depth) of the Si grating teeth is controlled to be 180 nm, resulting in an x-ray phase grating of a duty cycle (defined as the ratio of the low x-ray refractive index decrement δ material teeth width to the grating pitch) of 30% after WN filling. FIG. 8 shows the cross-section SEM image of a fabricated device.

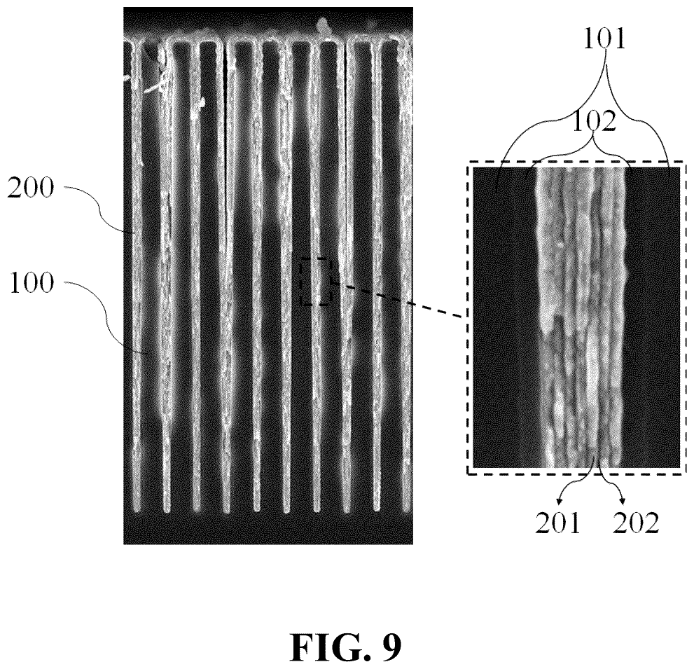

In one embodiment of the fabrication process, a Si grating mold 101 (refer to FIG. 9) of 600 nm pitch, 9.5 μm depth was fabricated via DRIE. The average Si grating 101 teeth width is controlled to 260 nm. A layer of 70 nm SiO₂ 102 was conformally ALD deposited using a bis(tert-butylamino)silane (SiH₂(NH^{t}Bu)₂, BTBAS) and O₂ plasma ALD process at 300° C. to adjust the overall Si/SiO₂ teeth width of the grating mold 100 to 400 nm. A stack of four 25 nm W 201/5 nm Al₂O₃ 202 bilayers were conformally deposited via ALD to fill the trenches of the grating mold. The W 201 ALD was performed using a WF₆—Si₂H₆ process at 300° C. The Al₂O₃ 202 ALD was performed using Trimethylaluminum (TMA) and H₂O precursors at 300° C. The final device is an x-ray phase grating of 600 nm with a duty cycle of ≈67%. FIG. 9 shows the cross-section SEM images of a fabricated device, where the zoom-in view shows the details of the multiple thin film layers.

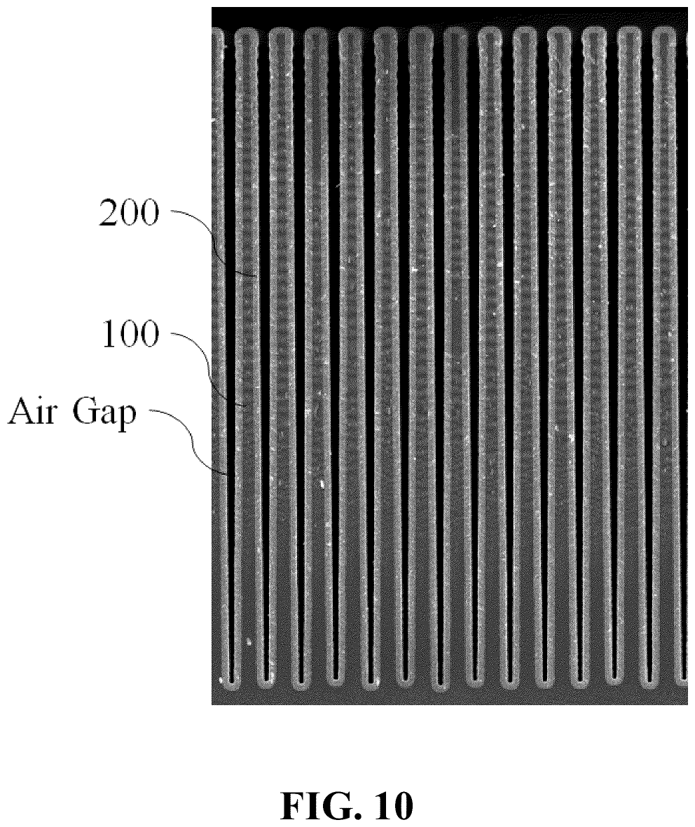

In one embodiment of the fabrication process, a Si grating mold 100 (refer to FIG. 10) of 600 nm pitch, 11 μm depth was fabricated via DRIE. The average width of the Si grating teeth is controlled to ≈180 nm. A layer of ≈120 nm WN 200 was conformally deposited via ALD with Bis(tert-butylimido)-bis(dimethylamido)tungsten(VI) (((CH₃)₃CN)₂W(N(CH₃)₂)₂) and ammonia (NH₃) precursors at 300° C. to produce a high x-ray refractive index decrement δ film on each side of a Si grating tooth. The ≈180 nm average width air gaps were left unfilled and function as low δ grating teeth. The final device is approximately a 300 nm period x-ray phase grating with a duty cycle of ≈60%. FIG. 10 shows the cross-section SEM image of a fabricated device.

What is claimed is:

1. A method for producing x-ray phase gratings for x-ray multi-contrast imaging (including phase, dark-field and absorption contrasts), comprising the steps of:
a) Create a high aspect ratio grating mold with low x-ray refractive index decrement δ material or materials;
b) Conformally deposit material (or materials) with high x-ray refractive index decrement δ (or high δ in average) via ALD to fill the trenches of the grating mold.

2. The method for producing x-ray gratings according to claim 1, wherein the grating mold is a Si grating.

3. The method for producing x-ray gratings according to claim 1, wherein the grating mold consists of a Si grating and a thin film (includes but not limited to SiO₂, Al₂O₃) with x-ray refractive index decrement δ close to that of Si, conformally deposited on the grating teeth to adjust the grating duty cycle.

4. The method for producing x-ray gratings according to claim 1, wherein cross bridges are used in the grating mold to improve the mechanical property of the mold.

5. The grating mold according to claim 3, where in the thin film material is SiO₂ and deposited via ALD, or dry oxidation, or wet oxidation.

6. The grating mold according to claim 3, where in the thin film material is Al₂O₃ and deposited via ALD.

7. The method for producing x-ray gratings according to claim 1, wherein the high x-ray refractive index decrement δ material is a compound deposited via conformal ALD and the compound material includes (but not limited to) WN, TaN and HfN.

8. The method for producing x-ray gratings according to claim 1, wherein the high x-ray refractive index decrement δ materials consist of a stack of alternating high-δ/low-δ compounds; the high δ compound includes (but not limited to) WN, TaN and HfN, the low δ compound includes (but not limited to) Al₂O₃ and SiO₂; the percentage (in volume) of the high δ material is preferred to be at least 80%.

9. The method for producing x-ray gratings according to claim 1, wherein the high x-ray refractive index decrement δ materials consist of a stack of alternating high atomic number metal/dielectric layers; the high atomic number metal includes (but not limited to) W, Ta, Pt, Au, and Ir, the dielectric material is preferred (but not limited to) to be Al₂O₃; The percentage (in volume) of the metal is preferred to be at least 80%.

10. The method for producing x-ray gratings according to claim 1, wherein the high x-ray refractive index decrement δ material is a high atomic number metal; the high atomic number metal includes (but not limited to) W, Ta, Pt, Au, and Ir; the ALD is preferably performed at low temperature (for example, <150° C.) to avoid delamination.

11. A method for producing x-ray phase gratings for x-ray multi-contrast imaging, comprising the steps of:
a) Create a high aspect ratio grating mold with low x-ray refractive index decrement δ material or materials, where the grating teeth width is less than ½ the grating mold period, preferably approximately ¼ the grating mold period;
b) Conformally coat material (or materials) with high x-ray refractive index decrement δ (or high δ in average) via ALD such that the sum of the grating mold teeth width and the deposited material (or materials) thickness is approximately half the grating period;
c) Leave the air gap unfilled, or conformally coat material (or materials) with δ (or δ in average) close to that of the material (or materials) of the teeth of the mold grating to fill the airgap.

12. The method for producing x-ray gratings according to claim 11, wherein the grating mold is a Si grating.

13. The method for producing x-ray gratings according to claim 11, wherein the grating mold consists of a Si grating and a thin film with x-ray refractive index decrement δ close to that of Si conformally deposited on the grating teeth to adjust the grating duty cycle; the thin film material includes (but not limited to) SiO₂ (deposited by wet or dry oxidation, or ALD), Al₂O₃ (deposited via ALD).

14. The method for producing x-ray gratings according to claim 11, wherein cross bridges are used in the grating mold to improve the mechanical property of the mold.

15. The method for producing x-ray gratings according to claim 11, wherein the high x-ray refractive index decrement δ material is a compound deposited via conformal ALD, and the compound material includes (but not limited to) WN, TaN and HfN.

16. The method for producing x-ray gratings according to claim 11, wherein the high x-ray refractive index decrement δ materials consist of a stack of alternating high δ/low δ compounds; the high δ compound includes (but not limited to) WN, TaN and HfN, the low δ compound includes (but not limited to) Al₂O₃ and SiO₂; The percentage (in volume) of the high δ material is preferred to be at least 80%.

17. The method for producing x-ray gratings according to claim 11, wherein the high x-ray refractive index decrement δ materials consist of a stack of alternating high atomic number metal/dielectric layers; the high atomic number metal includes (but not limited to) W, Ta, Pt, Au, and Ir, the dielectric material is preferred (but not limited to) to be Al₂O₃; the percentage (in volume) of the metal is preferred to be at least 80%.

18. The method for producing x-ray gratings according to claim 11, wherein the high x-ray refractive index decrement δ material is a high atomic number metal; the high atomic number metal includes (but not limited to) W, Ta, Pt, Au, and Ir; the ALD is preferably performed at low temperature (for example, <150° C.) to avoid delamination.

19. The method for producing x-ray gratings according to claim 11, wherein the material to fill the airgap after the deposition of high x-ray refractive index decrement δ material (or materials) includes (but not limited to) SiO₂ and Al₂O₃, deposited by ALD.
